(19) United States
(12) Patent Application Publication
(10) Pub. No.: US 2008/0256343 A1
(43) Pub. Date: Oct. 16, 2008

(54) Convergence determination and scaling factor estimation based on sensed switching activity or measured power consumption

(75) Inventors: Warren J. Gross, Montreal (CA); Shie Mannor, Montreal (CA)

Correspondence Address: FREEDMAN & ASSOCIATES, 117 CENTREPOINTE DRIVE, SUITE 350, NEPEAN, ONTARIO, K2G 5X3, CA

(73) Assignee: The Royal Institution for the advancement of Learning/McGill University, Montreal (CA)

(21) Appl. No.: 12/081,155

(22) Filed: Apr. 11, 2008

Related U.S. Application Data
(60) Provisional application No. 60/907,606, filed on Apr. 11, 2007.

(51) Int. Cl. H01R 13/60; H03K 19/003

(52) U.S. Cl. 712/223; 326/9

(57) ABSTRACT

A method and system for determining convergence of iterative processes and estimating a scaling factor in decoding processes based on switching activity of the logic circuitry are provided. During execution of an iterative process using logic circuitry comprising logic gates switching activity of a plurality of the logic gates is sensed to determine switching data indicative of a total switching activity of the plurality of the logic gates. The iterative process is iterated using the logic circuitry until convergence is indicated by the switching data. Similarly, a scaling factor for use in decoding processes is determined based on the switching data.

This application claims the benefit of U.S. Provisional Patent Application No. 60/907,606 filed Apr. 11, 2007, the entire contents of which are incorporated herein by reference.

### FIELD OF THE INVENTION

The instant invention relates generally to controlling processes executed using logic circuitry, and more particularly to methods and systems for determining convergence of iterative processes and estimating a scaling factor in decoding processes based on switching activity of the logic circuitry.

### BACKGROUND

With the advent of computer technology applications based on iterative processes have become increasingly important and are now a mainstay of countless present day applications such as, for example, numerical computation, iterative decoding, and adaptive filtering.

A major problem of the execution of iterative processes is the determination of the iterative process having converged to a solution. Typically, iterative processes are either performed for a preset number of iterations or by performing additional computation for determining if a stopping criterion has been fulfilled. In the first case the number of iterations is determined such that a likelihood that iterative processes have converged within this number of iterations is high, i.e. convergence is achieved in worst case scenarios. Therefore, most iterative processes have converged but are still continued until the predetermined number of iterations has been performed, requiring substantial processing capabilities and time. In the second case additional computation is performed—usually comprising complex matrix calculations—to determine convergence, again requiring substantial processing capabilities and time.

Furthermore, in numerous iterative processes such as for example iterative decoding processes, a scaling factor is applied to input signal data in order to ensure proper processing of the same. For example, in stochastic decoding processes a scaling factor is applied to the input signal data to ensure a level of switching activity such that nodes are prevented from locking in a hold state. In state of the art decoding processes simulated code words are used to determine the scaling factor based on the Bit Error Rate (BER) performance of the decoding process, requiring substantial processing capabilities and time.

It would be advantageous to provide a method and system that overcome at least some of the above-mentioned limitations.

### SUMMARY OF EMBODIMENTS OF THE INVENTION

In accordance with an aspect of the present invention there is provided a method comprising:

executing an iterative process using logic circuitry comprising logic gates;
sensing switching activity of a plurality of the logic gates to determine switching data indicative of a total switching activity of the plurality of the logic gates;
iterating the iterative process using the logic circuitry until convergence is indicated by the switching data, the convergence indicated by an amount of switching activity below a predetermined threshold; and,
providing output data determined by the iterative process.

In accordance with an aspect of the present invention there is provided a method comprising:

executing an iterative process using logic circuitry comprising logic gates;
sensing switching activity of a logic gate to determine switching data indicative of a total switching activity of the logic gate;
iterating the iterative process using the logic circuitry until one of convergence, divergence, anomaly and error is indicated by the switching data; and,
providing one of output data determined by the iterative process, data indicative of the divergence, and data indicative of the anomaly.

In accordance with an aspect of the present invention there is provided a method comprising:

executing a first portion of a decoding process using logic circuitry comprising logic gates;
sensing switching activity of a plurality of the logic gates to determine switching data indicative of a total switching activity of the plurality of the logic gates;
determining a scaling factor based on the switching data; and,
using the logic circuitry executing a second portion of the decoding process with the scaling factor being applied to at least a portion of data of the second portion of the decoding process.

In accordance with an aspect of the present invention there is provided a method comprising:

executing a plurality of processes using different portions of a logic circuitry comprising logic gates;
sensing switching activity of a plurality of the logic gates of each portion of the logic circuitry to determine switching data indicative of a total switching activity of the plurality of the logic gates of each portion of the logic circuitry; and,
allocating resources to each of the plurality of processes in dependence upon the switching data.

In accordance with an aspect of the present invention there is provided a method comprising:

processing signal data using logic circuitry comprising logic gates;
sensing switching activity of a plurality of the logic gates to determine switching data indicative of a total switching activity of the plurality of the logic gates;
determining data indicating a change in the signal data if the switching data are indicative of a change of the total switching activity of the plurality of the logic gates; and,
providing the data indicating a change.

In accordance with an aspect of the present invention there is provided a method comprising:

providing data of two datasets to respective input ports of logic gates of a logic circuitry;
sensing switching activity of a plurality of the logic gates to determine switching data indicative of a total switching activity of the plurality of the logic gates;
determining data indicative of one of a similarity and dissimilarity between the two datasets in dependence upon the switching data; and,
providing the data indicative of one of a similarity and dissimilarity.

In accordance with an aspect of the present invention there is provided a system comprising:

logic circuitry comprising a plurality of logic gates, the logic circuitry for executing a process; sensing circuitry connected to the logic circuitry, the sensing circuitry for sensing switching activity of a at least some logic gates of the plurality of the logic gates; and,
process control circuitry connected to the sensing circuitry and the logic circuitry, the process control circuitry for performing:
determining switching data in dependence upon a total switching activity of the at least some logic gates of the plurality of logic gates; and,
providing data in dependence upon the switching data to the logic circuitry for executing the process on the logic circuitry in dependence upon the switching data.

In accordance with an aspect of the present invention there is provided a system comprising:

sensing circuitry for being connected to logic circuitry comprising logic gates for executing a process, the sensing circuitry for sensing switching activity of a plurality of the logic gates; and,
process control circuitry connected to the sensing circuitry and for being connected to the logic circuitry, the process control circuitry for performing:
determining switching data in dependence upon a total switching activity of the plurality of the logic gates; and,
providing data in dependence upon the switching data to the logic circuitry for executing the process on the logic circuitry in dependence upon the switching data.

### BRIEF DESCRIPTION OF THE DRAWINGS

Exemplary embodiments of the invention will now be described in conjunction with the following drawings, in which:

FIGS. 1a to 1d are simplified block diagrams illustrating various embodiments of a system for controlling execution of a process according to the invention;

FIG. 2a is a simplified flow diagram of a method for determining convergence of an iterative process according to an embodiment of the present invention;

FIG. 2b is a simplified flow diagram of a method for determining a scaling factor in a decoding process according to an embodiment of the present invention;

FIG. 2c is a simplified flow diagram of a method for allocating processing resources according to an embodiment of the present invention;

FIG. 2d is a simplified flow diagram of a method for detecting a change in signal data according to an embodiment of the present invention; and,

FIG. 2e is a simplified flow diagram of a method for comparing two datasets according to an embodiment of the present invention.

### DETAILED DESCRIPTION OF EMBODIMENTS OF THE INVENTION

The following description is presented to enable a person skilled in the art to make and use the invention, and is provided in the context of a particular application and its requirements. Various modifications to the disclosed embodiments will be readily apparent to those skilled in the art, and the general principles defined herein may be applied to other embodiments and applications without departing from the scope of the invention. Thus, the present invention is not intended to be limited to the embodiments disclosed, but is to be accorded the widest scope consistent with the principles and features disclosed herein.

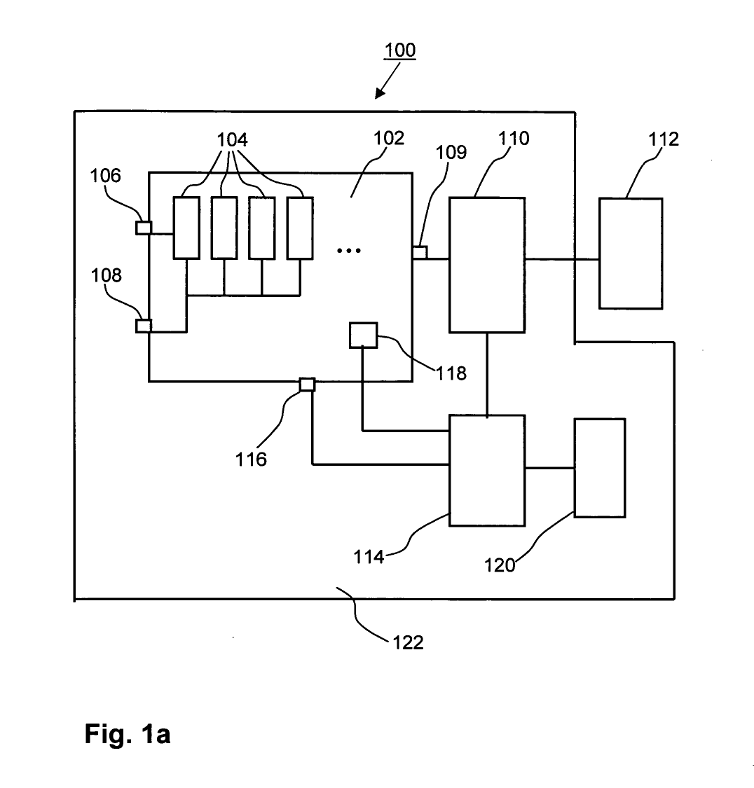

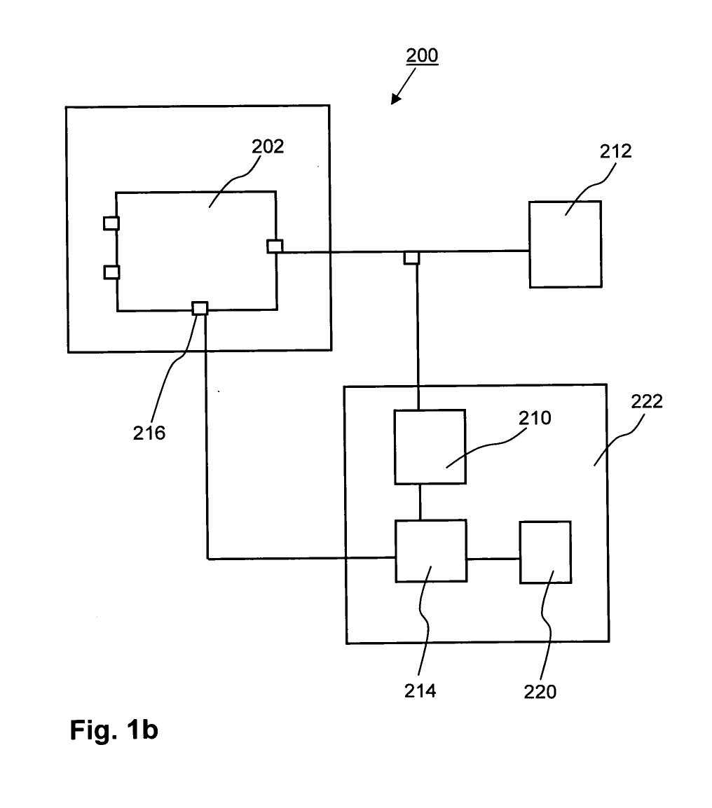

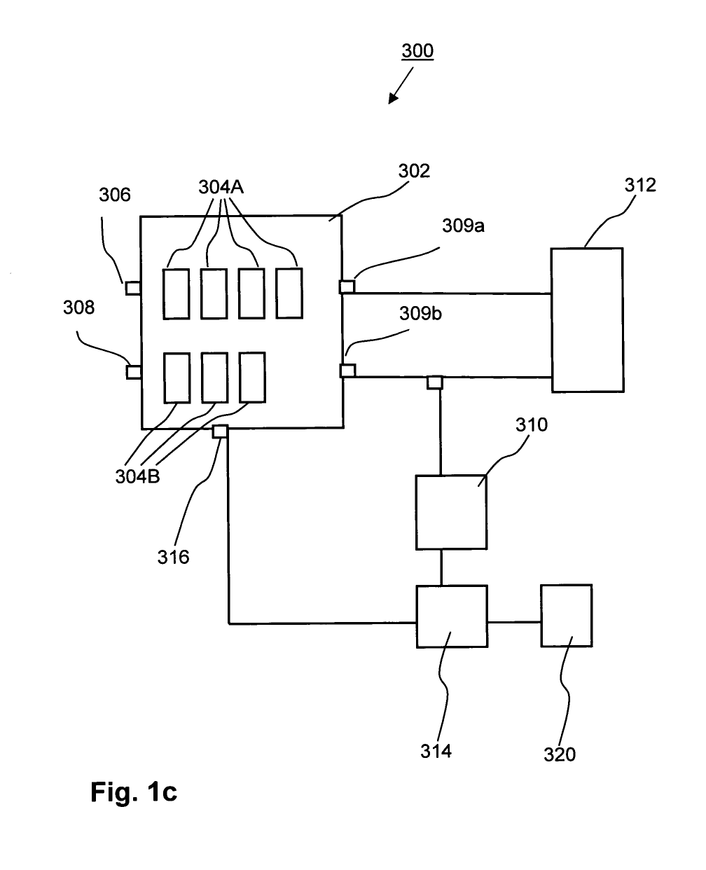

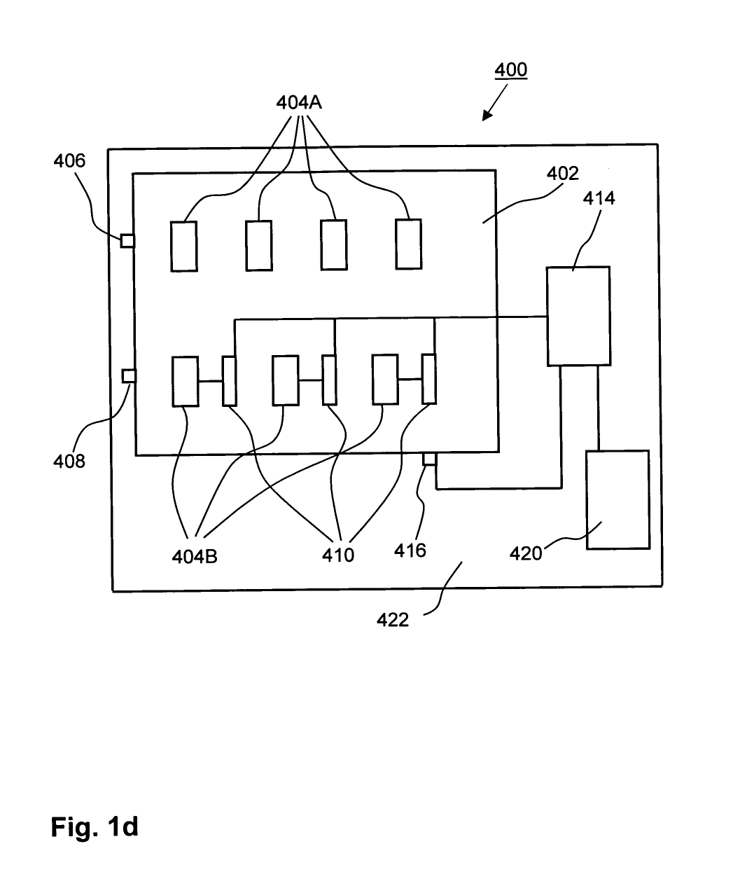

Referring to FIGS. 1a to 1d, various embodiments of a system for controlling execution of a process using logic circuitry comprising logic gates according to the present invention are shown. Processes such as iterative processes, decoding processes, and data comparing processes are controlled based on a total switching activity of a plurality of the logic gates as will be described hereinbelow. It will become apparent that each of the various embodiments shown in FIGS. 1a to 1d are employable for executing and controlling the iterative processes, decoding processes, and data comparing processes. Furthermore, it will become apparent that the embodiments according to the present invention, while being described in connection with digital logic circuitry, are also applicable in analog logic circuits used, for example, in analog decoding and analog computing.

Referring to FIG. 1a, a system 100 according to an embodiment of the invention is shown. The system 100 comprises logic circuitry 102 such as, for example, a processor, with logic gates 104 for executing one of the above processes. In operation, input data are received at input port 106, processed using the logic gates 104 and output data are provided via output port 108. Power for operating the logic circuitry 102 is provided by a power supply 112, for example, a supply voltage V_{DD}, via power supply port 109.

Dynamic power consumption of a digital logic gate is expressed as:

P_{dyn}=C_{L}V²_{DD}p_{0→1}f, (1)

where P_{dyn} is the dynamic power consumption, f is the clock frequency, C_{L} is the load capacitance driven by the logic gate, V_{DD} is the supply voltage, and p_{0→1} is the frequency of 0-to-1 signal transitions, i.e. the dynamic power consumption is data-dependent. The total dynamic power consumption is then expressed as the sum of the dynamic power consumption of the individual logic gates. Therefore, the total dynamic power consumption of the logic circuitry 102 is dependent upon the sum of the signal transitions of its logic gates 104, i.e. the total switching activity of the logic gates 104.

Furthermore, the total switching activity of the logic gates 104 depends on the data processed. For example, when an iterative process has converged to a solution there are only little or no changes in the data processed resulting in a low total switching activity of the logic gates 104. Further, in decoding processes the total switching activity of the logic gates 104 varies with the Signal to Noise Ratio (SNR) of the input signal.

The relation between the total dynamic power consumption of the logic circuitry 102 and the data of the process executed using the logic circuitry 102 is exploited to control the process by measuring the total dynamic power consumption of the logic circuitry 102 or, alternatively, by measuring the total power consumption of the logic circuitry 102—with the total power consumption being the sum of the total dynamic power consumption and the total static power consumption—using a load measurement circuit 110 interposed between the power supply 112 and the power supply port 109. Load measurement circuits measure, for example, average power consumption of a plurality of clock cycles or power consumption per clock cycle using, for example, current measurement techniques such as high frequency measurement techniques using, for example, a measurement circuit comprising low-resistance fast Field Effect Transistor (FET) switches and high frequency capacitors. Referring still to FIG. 1a, the measured power consumption is then provided to process control circuitry 114, which provides control data to the logic circuitry 102 via control port 116.

For example, during execution of an iterative process using the logic circuitry 102 total power consumption is measured and compared to a predetermined threshold. If the total power consumption is below the predetermined threshold—indicative of the iterative process being converged—control data indicative of convergence are provided to the logic circuitry 102 via the control port 116. Upon receipt of the control data the logic circuitry 102 stops the iterative process and provides output data via the output port 108.

Optionally, the process control circuitry 114 is connected to at least one temperature sensor 118 disposed within the logic circuitry 102 for measuring temperature of the logic circuitry 102. This allows accounting for the temperature dependence of the power consumption of the logic circuitry 102 providing increased accuracy of the control data.

Further optionally, the process control circuitry 114 is connected to memory 120, the memory 120 for storing a plurality of predetermined thresholds and/or control data. This adds flexibility to the system by enabling retrieval of different predetermined thresholds and/or control data for different processes executed and, furthermore, enabling a process of self-learning during, for example, a calibration procedure. The control process performed by the process control circuitry 114 is performed, for example, in hardware implemented fashion or, alternatively, by executing executable commands stored, for example, in the memory 120, using the process control circuitry 114.

As shown in FIG. 1a, it is possible to integrate the components of the system 100 on a single chip 122. Furthermore, it is possible to implement the system 100 using a Field Programmable Gate Array (FPGA).

Alternatively, as shown in system 200 in FIG. 1b, load measurement circuit 210, process control circuitry 214 and memory 220 are integrated on a separate embedded system 222 with the load measurement circuit 210 being connected to power supply 212 of logic circuitry 202 and process control circuitry 214 being connected to control input port 216 of the logic circuitry 202. For, example, the system 200 enables implementation of switching activity based process control as a retrofit for existing processing systems.

Referring to FIG. 1c, a system 300 according to an embodiment of the invention is shown. The system 300 comprises logic circuitry 302 such as, for example, a processor with logic gates 304A and 304B for executing one of the above processes. In operation, input data are received at input port 306, processed using the logic gates 304A and 304B and output data are provided via output port 308. Power for operating the logic circuitry 302 is provided by a power supply 312, for example, a supply voltage V_{DD}, via power supply ports 309A and 309B. Here, load measurement circuit 310 is connected only to the power supply of the logic gates 304B via power supply port 309B. The measured power consumption is then provided to process control circuitry 314, which provides control data to the logic circuitry 302 via control port 316.

For example, during execution of an iterative process using the logic circuitry 302 only the total power consumption of the logic gates 304B is measured and compared to a predetermined threshold. For example, the logic gates 304B are the logic gates determining a portion of the iterative process that is indicative of convergence such as up/down counters of a stochastic decoder or logic gates determining a given bit position such as the Most Significant Bit (MSB). If the total power consumption is below the predetermined threshold—indicative of the iterative process being converged—control data indicative of convergence are provided to the logic circuitry 302 via the control port 316. Upon receipt of the control data the logic circuitry 302 stops the iterative process and provides output data via the output port 308.

Referring to FIG. 1d, a system 400 according to an embodiment of the invention is shown. The system 400 comprises logic circuitry 402 such as, for example, a processor, with logic gates 404A and 404B for executing one of the above processes. In operation, input data are received at input port 406, processed using the logic gates 404A and 404B and output data are provided via output port 408. Here, the total switching activity of the logic gates 404B is directly measured by connecting, for example, a counter 410 to an output port of each respective logic gate 404B. The counters 410 are implemented using, for example, a Flip-Flop design. The counters 410 are connected to process control circuitry 414. The measured total switching activity of the logic gates 404B is then provided to the process control circuitry 414, which provides control data to the logic circuitry 402 via control port 416.

For example, during execution of an iterative process using the logic circuitry 402 the total switching activity of the logic gates 404B is measured and compared to a predetermined threshold. For example, the logic gates 404B are the logic gates determining a portion of the iterative process that is indicative of convergence such as up/down counters of a stochastic decoder or logic gates determining a given bit position such as the Most Significant Bit (MSB). If the total switching activity is below the predetermined threshold—indicative of the iterative process being converged—control data indicative of convergence are provided to the logic circuitry 402 via the control port 416. Upon receipt of the control data the logic circuitry 402 stops the iterative process and provides output data via the output port 408.

As shown in FIG. 1d, the components of the system 400 are optionally integrated on a single chip 422. Furthermore, the system 400 is optionally implemented using a Field Programmable Gate Array (FPGA).

Optionally, the process control circuitry 414 is connected to memory 420, the memory 420 for storing a plurality of predetermined thresholds and/or control data. This adds flexibility to the system by enabling retrieval of different predetermined thresholds and/or control data for different processes executed and, furthermore, enabling a process of self-teaching during, for example, a calibration procedure. The control process performed by the process control circuitry 414 is performed, for example, in hardware implemented fashion or, alternatively, by executing executable commands stored, for example, in the memory 420, using the process control circuitry 414.

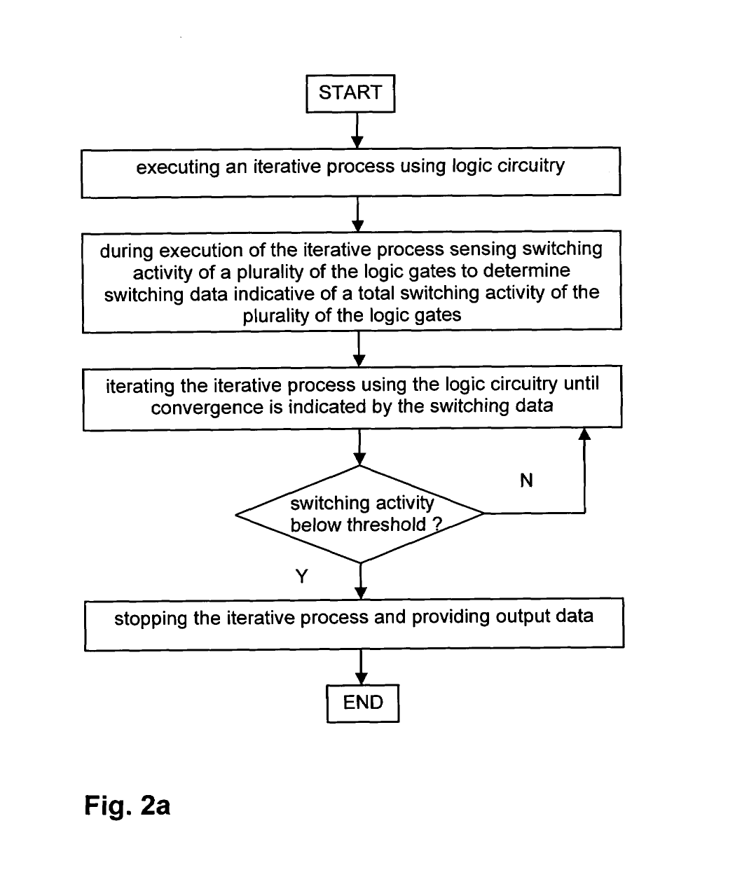

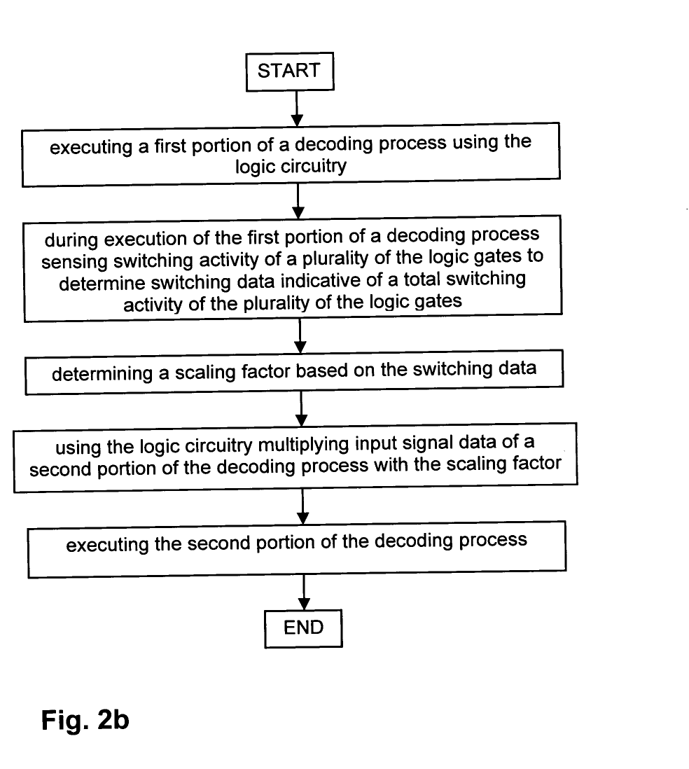

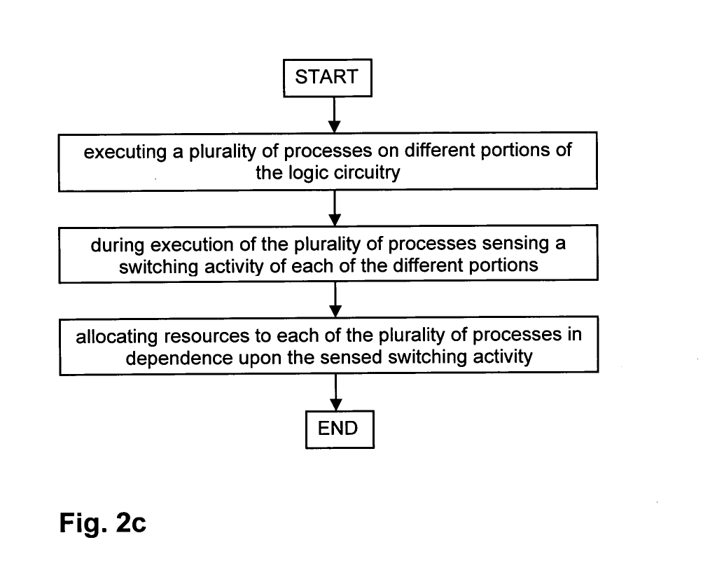

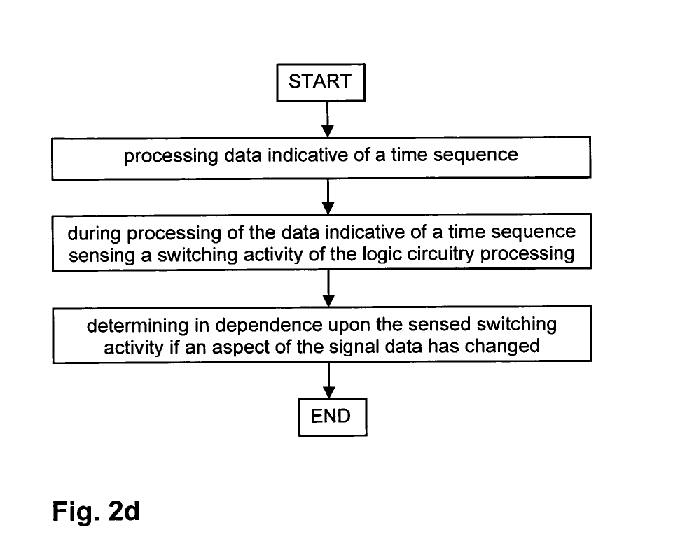

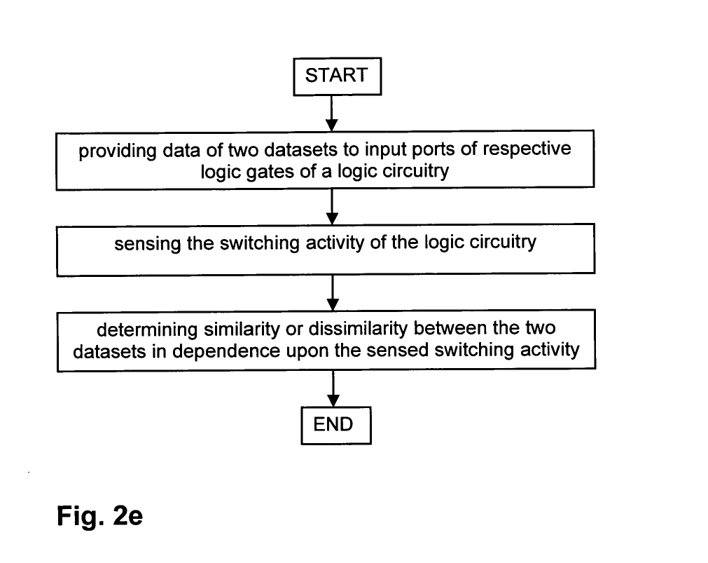

Referring to FIG. 2a, a simplified flow diagram of a method for determining convergence of an iterative process according to an embodiment of the present invention is shown. At 10 an iterative process is executed using the logic circuitry. During execution of the iterative process switching activity of a plurality of the logic gates is sensed to determine switching data indicative of a total switching activity of the plurality of the logic gates—12. The iterative process is iterated using the logic circuitry until convergence is indicated by the switching data—14. The convergence is indicated by an amount of switching activity below a predetermined threshold—16. After convergence is indicated, the iterative process is stopped and output data are provided—18.

For example, the switching activity is sensed at predetermined time intervals during execution of the iterative process. To reduce processing, the process of sensing switching activity is optionally started after elapse of a predetermined initial execution time interval during which convergence of the iterative process is not expected to take place. Depending on system characteristics such as processing time and accuracy, the switching activity is sensed per clock cycle of the logic circuitry or is sensed over a predetermined number of clock cycles of the logic circuitry. Load measurement circuits capable of measuring power consumption per clock cycle operate, for example, at twice the clock speed of the logic circuitry.

The above method and its implementations of sensing of the switching activity and its timing are implementable using each of the systems shown in FIGS. 1a to 1d.

Using the systems shown in FIGS. 1a to 1c, the switching activity is sensed by measuring one of total power consumption and dynamic power consumption of the logic circuitry. Since the dynamic power consumption is dependent on the switching activity of the logic gates—equation (1)—the power consumption is measured and the measured power consumption is compared to a predetermined threshold using the process control circuitry. Alternatively, a switching activity is determined based on the measured power consumption using the process control circuitry. Optionally, measurement data provided by a temperature sensor disposed within the logic circuitry is used to account for variations of the power consumption of the logic circuitry due to temperature variations. Alternatively, the switching activity is directly sensed using logic sensing circuitry comprising, for example, the counters 410, as shown in FIG. 1d.

Optionally, data indicative of at least one of predetermined thresholds, predetermined initial execution time interval, and predetermined number of clock cycles are stored in the memory, for example, in the form of a lookup table and are retrieved by the process control circuitry. For example, the process control circuitry receives from the logic circuitry via the control port control data indicative of the iterative process and the process control circuitry then retrieves the respective data from the memory.

For example, the thresholds are determined through experimentation by executing various iterative processes on the logic circuitry, determining convergence by other means—for example, calculating if a given convergence criterion has been met—and sensing the corresponding switching activity. Alternatively, the thresholds are determined theoretically based on knowledge of the data processed in the iterative process and the design of the logic circuitry using, for example, density evolution techniques. Further alternatively, the thresholds are determined in a self-learning process, for example, the thresholds are determined through experimentation by executing various iterative processes on the logic circuitry, determining convergence by other means and sensing the corresponding switching activity. Such a self-learning process is, for example, executed during calibration using various predetermined test signals in decoding or adaptive filtering.

Optionally, test and calibration circuitry is included within the circuit and calibration is performed by the circuit to determine a switching threshold and an associated power consumption for a converged process and data set. During normal operation of the circuit the test and calibration circuitry is disabled such that it does not consume power. The inclusion of the test and calibration circuitry within the circuit enables, for example, recalibration and testing internal to the circuit in case of, for example, poor performance.

Further optionally, data indicative of a change or gradient of the total switching activity between sensed switching activities are determined and used for determining convergence of the iterative process. Alternatively, data indicative of a change or gradient of the power consumption are determined. During execution of numerous types of iterative processes the switching activity decreases when the iterative process converges to a solution and the switching activity remains substantially constant after convergence of the iterative process, i.e. larger values of the change of the switching activity are followed by values of the change of the switching activity close to zero or equal to zero. This enables determining the convergence of an iterative process without predetermined thresholds for the switching activity or, alternatively, provides an additional switching activity based indicator of convergence in situations where the switching activity stays above the predetermined threshold.

Optionally, in order to reduce processing of the process control circuitry, the switching activity of only a predetermined portion of the logic circuitry is sensed—using one of the systems shown in FIGS. 1c and 1d. For example, in statistical decoding only the switching activity of logic gates performing the function of equality nodes or logic gates performing the function of up/down counters is sensed. This enables a more accurate determination of the convergence and reduces processing. In another example, only the switching activity of logic gates related to processing of a predetermined bit position—for example, the Most Significant Bit (MSB)—is sensed. Again, processing of the process control circuitry is substantially reduced while accuracy is increased.

Additionally, the above method provides a simple and effective method for detecting divergence—when an iterative process fails to converge—or anomalies—when the iterative process produces unexpected data resulting in a different pattern of power consumption during execution. For example, during execution of the iterative process the power consumption—or switching activity—is sensed at predetermined time intervals and compared to predetermined thresholds corresponding to each predetermined time interval. If the sensed power consumption is outside a predetermined range, the process control circuitry determines control data indicative of divergence or an anomaly. Based on the control data, execution of the process is stopped or corrective action is taken such as determining a scaling factor for scaling data determined by the iterative process in step i for use in a following iteration step in order for the process to converge. Furthermore, this method is beneficial for detecting an error occurring during execution of a stochastic decoding process. If an error occurs during execution of a stochastic decoding process it is reflected in the power consumption. Again, sensing the power consumption during execution of the stochastic decoding process at predetermined time intervals and comparing the sensed power consumption to predetermined thresholds corresponding to each predetermined time interval reveals presence of an error occurring during execution. Alternatively, statistically evaluating a series of sensed power consumption data against a known progression allows for detection of errors and anomalies.

Referring to FIG. 2b, a simplified flow diagram of a method for determining a scaling factor in a decoding process according to an embodiment of the present invention is shown. For example, in stochastic decoding scaling is applied to input signal data to ensure a level of switching activity such that nodes are prevented from locking in a hold state. As is evident, the method is not limited to stochastic decoding but is also applicable in numerous other iterative decoding processes. At 30 a first portion of a decoding process is executed using the logic circuitry. During execution of the first portion of a decoding process switching activity of at least a plurality of the logic gates is sensed to determine switching data indicative of a total switching activity of the plurality of the logic gates—32. Based on the switching data a scaling factor is determined—34. Using the logic circuitry input signal data of a second portion of the decoding process are multiplied with the scaling factor—36—and the second portion of the decoding process is executed—38. For example, a plurality of sets of encoded samples is successively received at a decoder. During decoding of the first set the switching activity is sensed and a scaling factor is determined in dependence thereupon for multiplying the encoded samples of the second set. The switching activity sensed during decoding of the second set is then used for determining a scaling factor for use with the third set, and so on. This process ensures a substantially constant level of switching activity in the presence of varying signal quality—Signal to Noise Ratio (SNR)—of the received sets of encoded samples. Optionally, the received first set of encoded samples is stored in a buffer prior to decoding. This allows decoding of the first set and determining of the switching activity. If the switching activity is below a threshold indicative of a high likelihood of nodes being locked in a hold state, a scaling factor is determined and the decoding of the first set is repeated by retrieving the first set from the buffer and multiplying the encoded samples of the first set with the scaling factor. The following sets of encoded samples are then processed as described above.

For example, the switching activity is sensed at predetermined time intervals during execution of the decoding process. Optionally, to reduce processing the process of sensing switching activity is performed only during a predetermined first portion of the decoding process. Depending on system characteristics such as processing time and accuracy, the switching activity is sensed per clock cycle of the logic circuitry or is sensed over a predetermined number of clock cycles of the logic circuitry.

The above method and its implementations of sensing of the switching activity and its timing are implementable using each of the systems shown in FIGS. 1a to 1d and each of the variations in sensing switching activity described hereinabove.

Optionally, data indicative of various scaling factors in dependence upon a sensed switching are stored in the memory, for example in the form of a lookup table and are retrieved by the process control circuitry. For example, the process control circuitry receives from the logic circuitry via the control port control data indicative of the decoding process and in dependence upon the sensed switching activity, the process control circuitry then retrieves the respective scaling factor from the memory.

Alternatively, the switching activity is sensed during a calibration process using a test signal and a scaling factor determined therefrom is used for following data transmissions. Such a process is applicable where the signal quality is substantially constant or substantially constant for a longer period of time with the calibration being repeated at predetermined time intervals.

Again, in order to reduce processing of the process control circuitry, the switching activity of only a predetermined portion of the logic circuitry is sensed—using one of the systems shown in FIGS. 1c and 1d. For example, in statistical decoding only the switching activity of logic gates performing the function of equality nodes is sensed. In another example, only the switching activity of logic gates related to processing of a predetermined bit position—for example, the MSB—is sensed.

Referring to FIG. 2c, a simplified flow diagram of a method for allocating processing resources according to an embodiment of the present invention is shown. At 40, a plurality of processes are executed on different portions of the logic circuitry. During execution of the plurality of processes a switching activity of each of the different portions is sensed—42—for example, at predetermined time intervals. In dependence upon the sensed switching activity resources are allocated to each of the plurality of processes—44. Resources are, for example, provision of power and portions of the logic circuitry. For example, if a portion of the logic circuitry has a high switching activity during execution of a process more power is allocated thereto, for example, by increasing a frequency of its clock, and if a portion of the logic circuitry has a low switching activity during execution of a process less power is allocated thereto, for example by operating that circuit portion with a slower clock. This allows power provision to various portions of the logic circuitry according to processing needs. Furthermore, if one or more portions of the logic circuitry executing a process “A” experience a high switching activity, then further portions of the logic circuitry are allocated to the process “A.” Optionally, the allocation is employed in dependence upon a type of logic gates needed most for executing the process “A.” For example, if the sensed switching activity is indicative of logic gates of type D experience a high switching activity more logic gates of type D are allocated to the process “A.”

Referring to FIG. 2d, a simplified flow diagram of a method for detecting a change in signal data according to an embodiment of the present invention is shown. At 50, received signal data such as data indicative of a time sequence are processed. During processing of the signal data, a switching activity of the logic circuitry processing the signal data is sensed—52—for example, at predetermined time intervals. In dependence upon the sensed switching activity, it is then determined if a characteristic of the signal data has changed—54. This provides a simple method for detecting a change in the signal data by sensing the switching activity or measuring the power consumption of the logic circuitry. The method is applicable in numerous applications, for example, for detecting a change in the signal quality of received signal data allowing determining of an appropriate filter function or scaling factor for further processing.

Referring to FIG. 2e, a simplified flow diagram of a method for comparing two datasets according to the present invention is shown. At 60, data of two datasets are provided to input ports of respective logic gates—for example, AND gates—of a logic circuitry and the switching activity of the logic circuitry is then sensed—62. A similarity or dissimilarity between the two datasets is then determined in dependence upon the sensed switching activity—64. This method provides a simple process for determining similarity or dissimilarity between two large datasets such as 2D or 3D image data and allows, for example, fast detection of small differences between large datasets in chaos theory.

Numerous other embodiments of the invention will be apparent to persons skilled in the art without departing from the spirit and scope of the invention as defined in the appended claims.

What is claimed is:

1. A method comprising:
executing an iterative process using logic circuitry comprising logic gates;
sensing switching activity of a plurality of the logic gates to determine switching data indicative of a total switching activity of the plurality of the logic gates;
iterating the iterative process using the logic circuitry until convergence is indicated by the switching data, the convergence indicated by an amount of switching activity below a predetermined threshold; and,
providing output data determined by the iterative process.

2. A method as defined in claim 1 wherein the switching activity is sensed by measuring one of a total and a dynamic power consumption.

3. A method as defined in claim 1 wherein the switching activity is sensed using logic sensing circuitry.

4. A method as defined in claim 1 wherein the switching activity is sensed at predetermined time intervals.

5. A method as defined in claim 1 wherein the switching activity is sensed after elapse of a predetermined initial execution time interval.

6. A method as defined in claim 1 wherein the switching activity is sensed per clock cycle of the logic circuitry.

7. A method as defined in claim 1 wherein the switching activity is sensed over a predetermined number of clock cycles of the logic circuitry.

8. A method as defined in claim 1 comprising determining data indicative of a change of the total switching activity between sensed switching activities.

9. A method as defined in claim 1 wherein the switching activity of logic gates related to processing of a predetermined bit position is sensed.

10. A method as defined in claim 9 wherein the switching activity of logic gates related to processing of a most significant bit is sensed.

11. A method as defined in claim 1 wherein the switching activity of logic gates related to processing of a predetermined portion of the iterative process is sensed.

12. A method comprising:
executing an iterative process using logic circuitry comprising logic gates;
sensing switching activity of a logic gate to determine switching data indicative of a total switching activity of the logic gate;
iterating the iterative process using the logic circuitry until one of convergence, divergence, anomaly and error is indicated by the switching data; and,
providing one of output data determined by the iterative process, data indicative of the divergence, and data indicative of the anomaly.

13. A method as defined in claim 12 wherein the switching activity is sensed by measuring one of a total and a dynamic power consumption.

14. A method as defined in claim 12 wherein the switching activity is sensed using logic sensing circuitry.

15. A method as defined in claim 13 wherein the power is sensed using current measurement.

16. A method comprising:
executing a first portion of a decoding process using logic circuitry comprising logic gates;
sensing switching activity of a plurality of the logic gates to determine switching data indicative of a total switching activity of the plurality of the logic gates;
determining a scaling factor based on the switching data; and,
using the logic circuitry executing a second portion of the decoding process with the scaling factor being applied to at least a portion of data of the second portion of the decoding process.

17. A method as defined in claim 16 wherein the switching activity is sensed by measuring one of a total and a dynamic power consumption.

18. A method as defined in claim 16 wherein the switching activity is sensed using logic sensing circuitry.

19. A method as defined in claim 16 comprising:
multiplying input signal data of the second portion of the decoding process with the scaling factor.

20. A method as defined in claim 16 wherein the switching activity is sensed at predetermined time intervals.

21. A method as defined in claim 16 wherein the switching activity is sensed per clock cycle of the logic circuitry.

22. A method as defined in claim 16 wherein the switching activity is sensed over a predetermined number of clock cycles of the logic circuitry.

23. A method as defined in claim 16 comprising determining data indicative of a change of the total switching activity between sensed switching activities.

24. A method as defined in claim 16 wherein the switching activity of logic gates related to processing of a predetermined bit position is sensed.

25. A method as defined in claim 24 wherein the switching activity of logic gates related to processing of a most significant bit is sensed.

26. A method as defined in claim 16 wherein the switching activity of logic gates related to processing of a predetermined portion of the process is sensed.

27. A method comprising:
executing a plurality of processes using different portions of a logic circuitry comprising logic gates;
sensing switching activity of a plurality of the logic gates of each portion of the logic circuitry to determine switching data indicative of a total switching activity of the plurality of the logic gates of each portion of the logic circuitry; and,
allocating resources to each of the plurality of processes in dependence upon the switching data.

28. A method as defined in claim 27 wherein the switching activity is sensed by measuring one of a total and a dynamic power consumption.

29. A method as defined in claim 27 wherein the switching activity is sensed using logic sensing circuitry.

30. A method as defined in claim 27 wherein allocating resources comprises allocating power.

31. A method as defined in claim 27 wherein allocating resources comprises allocating portions of the logic circuitry.

32. A method comprising:
processing signal data using logic circuitry comprising logic gates;
sensing switching activity of a plurality of the logic gates to determine switching data indicative of a total switching activity of the plurality of the logic gates;
determining data indicating a change in the signal data if the switching data are indicative of a change of the total switching activity of the plurality of the logic gates; and,
providing the data indicating a change.

33. A method as defined in claim 32 wherein the switching activity is sensed by measuring one of a total and a dynamic power consumption.

34. A method comprising:
providing data of two datasets to respective input ports of logic gates of a logic circuitry;
sensing switching activity of a plurality of the logic gates to determine switching data indicative of a total switching activity of the plurality of the logic gates;
determining data indicative of one of a similarity and dissimilarity between the two datasets in dependence upon the determined switching data; and,
providing the data indicative of one of a similarity and dissimilarity.

35. A method as defined in claim 34 wherein the switching activity is sensed by measuring one of a total and a dynamic power consumption.

36. A system comprising:
logic circuitry comprising a plurality of logic gates, the logic circuitry for executing a process;
sensing circuitry connected to the logic circuitry, the sensing circuitry for sensing switching activity of a at least some logic gates of the plurality of the logic gates; and,
process control circuitry connected to the sensing circuitry and the logic circuitry, the process control circuitry for performing:
determining switching data in dependence upon a total switching activity of the at least some logic gates of the plurality of logic gates; and,
providing data in dependence upon the switching data to the logic circuitry for executing the process on the logic circuitry in dependence upon the switching data.

37. A system as defined in claim 36 wherein the sensing circuitry comprises load measurement circuitry connected to a power supply port of the at least some logic gates of the plurality of the logic gates, the load measurement circuitry for measuring one of total power consumption and dynamic power consumption of the at least some logic gates of the plurality of the logic gates.

38. A system as defined in claim 36 wherein the sensing circuitry comprises counters connected to each logic gate of the at least some logic gates of the plurality of the logic gates.

39. A system as defined in claim 36 wherein the at least some logic gates of the plurality of the logic gates comprises logic gates related to processing of a predetermined bit position.

40. A system as defined in claim 36 wherein the logic circuitry, the sensing circuitry, and the process control circuitry are integrated on a single chip.

41. A system as defined in claim 36 comprising memory connected to the process control circuitry, the memory for storing the switching data.

42. A system comprising:
sensing circuitry for being connected to logic circuitry comprising logic gates for executing a process, the sensing circuitry for sensing switching activity of a plurality of the logic gates; and,
process control circuitry connected to the sensing circuitry and for being connected to the logic circuitry, the process control circuitry for performing:
determining switching data in dependence upon a total switching activity of the plurality of the logic gates; and,
providing data in dependence upon the switching data to the logic circuitry for executing the process on the logic circuitry in dependence upon the switching data.
